(19) United States
(12) Patent Application Publication
(10) Pub. No.: US 2026/0135014 A1
(43) Pub. Date: May 14, 2026

(54) ELECTRON BEAM IRRADIATION DEVICE

(71) Applicant: NHV CORPORATION, Kyoto (JP)

(72) Inventors: Masahiro NAGAI, Kyoto (JP); Toshio KIMURA, Kyoto (JP)

(73) Assignee: NHV CORPORATION, Kyoto (JP)

(21) Appl. No.: 18/715,105

(22) PCT Filed: Dec. 5, 2022
(86) PCT No.: PCT/JP2022/044711

§ 371 Date: May 30, 2024

(30) Foreign Application Priority Data
Dec. 13, 2021 (JP) 2021-201918

(51) Int. Cl. G21K 5/04; H01J 37/063; H01J 37/065; H01J 37/18

(52) U.S. Cl. CPC G21K 5/04; H01J 37/063; H01J 37/065; H01J 37/18

(57) ABSTRACT

This electron beam irradiation device comprises: an acceleration tube (13) formed by providing, side by side in an axial direction (L1), a plurality of acceleration electrodes for generating an electric field for accelerating an electron beam; and a plurality of shield rings (40) which are provided side by side in the axial direction (L1) so as to form a pair with the acceleration electrodes on the radial outside of the acceleration tube (13), and which are formed by being electrically connected respectively to the acceleration electrodes that form the pair therewith. In addition, the electron beam irradiation device comprises a conductive shield member (50) which surrounds the radial outside of a ring group (40G) composed of the plurality of shield rings (40). The shield member (50) surrounds at least a portion in the axial direction (L1) in the ring group (40G).

### TECHNICAL FIELD

The present invention relates to an electron beam irradiation device.

### DESCRIPTION OF RELATED ART

An electron beam irradiation device is a device that irradiates a workpiece with a generated electron beam. Electron beam irradiation devices are used for purposes such as improving the properties of materials of, adding functions to, and sterilizing workpieces. Among electron beam irradiation devices, a scanning type electron beam irradiation device is equipped with an acceleration tube that converges and accelerates thermionic electrons generated from a filament in a vacuum to form an electron beam (for example, see Patent Literature 1). A filament is provided at one end unit of the acceleration tube in the axis direction. Further, multiple acceleration electrodes are disposed in parallel at equal intervals in the axis direction in the acceleration tube. A gradually higher voltage is applied to the acceleration electrodes as the acceleration electrodes are further away from the filament. As a result, an electric field for accelerating the electron beam is generated within the acceleration tube.

Moreover, the electron beam irradiation device of Patent Literature 1 has a shield ring for electric field relaxation around the acceleration tube. Multiple shield rings are provided, each corresponding to the acceleration electrodes. Each of the shield rings is electrically connected to the corresponding acceleration electrode so as to have the same potential.

### RELATED ART

### Patent Literature

Patent Literature 1: Japanese Patent Application Laid-Open No. 2-119399U

### SUMMARY

### Technical Problem

In the electron beam irradiation device as described above, an unstable electric field may be generated around the acceleration tube and the shield ring, for example, generated by a booster circuit that supplies a voltage to the filament and the acceleration electrodes. Then, the unstable electric field affects the electric field for accelerating the electron beam in the acceleration tube, and as a result, desired characteristics of the electron beam may be unable to be obtained.

The present invention has been made to solve the above problems, and an object of the present invention is to provide an electron beam irradiation device that may suppress the influence of the electric field around the shield ring.

### Solution to the Problem

An electron beam irradiation device that solves the above problems includes an acceleration tube in which multiple acceleration electrodes are disposed in parallel in an axis direction for generating an electric field that accelerates an electron beam; and multiple shield rings which are disposed in parallel in the axis direction to form a pair with the acceleration electrodes on a radially outer side of the acceleration tube, and respectively are electrically connected to the acceleration electrodes that form the pair therewith. The electron beam irradiation device includes a conductive shield member surrounding a radially outer side of a ring group composed of the shield rings, and the shield member surrounds at least a portion in the axis direction in the ring group.

According to the configuration, the influence of an unstable electric field around the shield ring on the acceleration tube may be suppressed by the shield member. Such a way makes it easier to obtain desired characteristics of the electron beam accelerated in the acceleration tube, thereby contributing to stabilizing the performance of the electron beam irradiation device, for example.

The electron beam irradiation device includes a power supply device which supplies power to the acceleration tube, and a pressure tank which accommodates the acceleration tube, the ring group, the shield member, and the power supply device.

According to the configuration, an unstable electric field is emitted from the power supply device within the pressure tank, and the unstable electric field may affect the surroundings of the acceleration tube. In this regard, according to the above configuration, the influence of the unstable electric field generated by the power supply device on the acceleration tube may be suitably suppressed by the shield member.

In the electron beam irradiation device, the shield member is electrically connected to the pressure tank and has the same potential as the pressure tank.

According to the configuration, by setting the shield member at the same potential as the pressure tank, the electric field around the acceleration tube inside the shield member may be suitably stabilized.

In the electron beam irradiation device, the acceleration tube includes a thermionic emission unit which emits thermoelectrons at one end unit in the axis direction of the acceleration tube. In the axis direction of the acceleration tube, an end unit side where the thermionic emission unit is provided is an upper stage side, and an opposite side thereof is a lower stage side. The acceleration tube emits an accelerated electron beam from an end unit of the lower stage side, and the pressure tank includes an exit port for emitting the electron beam emitted from the end unit of the lower stage side of the acceleration tube to the outside of the pressure tank. According to the configuration, the electron beam emitted from the acceleration tube may be emitted to the outside of the pressure tank through the exit port.

In the electron beam irradiation device, the shield member surrounds a portion in the axis direction in the ring group, and the shield member surrounds a radially outer side of at least the lowermost stage of the shield ring in the ring group.

According to the configuration, the potential difference between the shield member and the shield ring is larger toward the upper stage side. Therefore, by configuring the shield member to surround a portion of the lower stage side of the ring group, the occurrence of a short circuit due to discharge between the shield ring and the shield member may be suppressed.

In the electron beam irradiation device, the shield member surrounds all in the axis direction in the ring group.

According to the configuration, the influence of an unstable electric field around the shield ring on the acceleration tube may be more effectively suppressed by the shield member.

In the above electron beam irradiation device, the shield member includes a heat release hole which penetrates from an inner circumferential side to an outer circumferential side of the shield member.

According to the configuration, for example, heat generated by the acceleration electrode may be efficiently discharged to an outer side of the shield member.

### Effects

The electron beam irradiation device of the present invention exhibits the effect of suppressing the influence of the electric field around the shield ring.

### BRIEF DESCRIPTION OF THE DRAWINGS

FIG. 1 is a schematic configuration diagram of an electron beam irradiation device in an embodiment.

FIG. 2 is a schematic plan view showing a schematic configuration of the electron beam irradiation device in the same embodiment.

FIG. 3 is a schematic side view showing an acceleration tube unit in the same embodiment.

FIG. 4 is a schematic plan view showing the acceleration tube unit in the same embodiment.

FIG. 5 is a schematic plan view showing an acceleration tube unit in a modified example.

FIG. 6 is a schematic plan view showing an acceleration tube unit in a modified example.

### DESCRIPTION OF EMBODIMENTS

Hereinafter, an embodiment of an electron beam irradiation device will be described with reference to the drawings. Note that in the drawings, a part of the configuration may be exaggerated or simplified for convenience of description. Furthermore, the dimensional ratio of each part may also differs from the actual size.

### Overall Configuration of Electron Beam Irradiation Device

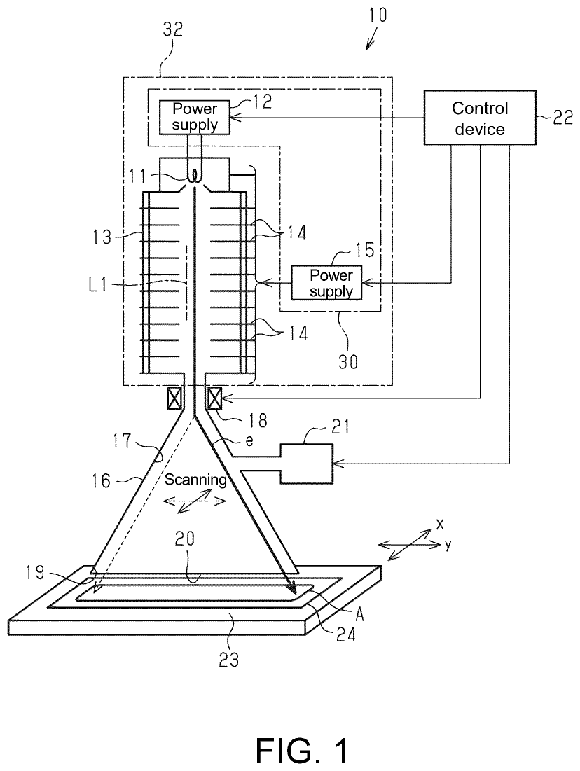

An electron beam irradiation device 10 of the embodiment shown in FIG. 1 is a scanning type electron beam irradiation device. The electron beam irradiation device 10 includes a filament 11 made of, for example, tungsten that emits thermoelectrons. The filament 11 emits electrons by heating the filament 11 itself based on the power supply from a filament power supply 12 included in a power supply device 30. The filament 11 is provided at one end unit of an acceleration tube 13. For example, the acceleration tube 13 is disposed in a posture such that an axis L1 direction of the acceleration tube 13 itself is horizontal. Note that, in the following description, in the axis L1 direction of the acceleration tube 13, an end unit side where the filament 11 is provided will be referred to as an upper stage side, and the opposite side thereof will be referred to as a lower stage side.

The acceleration tube 13 has a cylindrical shape with a closed upper end unit where the filament 11 is placed. The acceleration tube 13 has multiple acceleration electrodes 14 disposed in parallel in the axis L1 direction of the acceleration tube 13 itself. Based on the power supply from an acceleration electrode power supply 15 included in the power supply device 30, the acceleration electrode 14 generates an electric field that converges electrons emitted from the filament 11 and accelerates the electrons downward, which is the other end unit side in the axis L1 direction. That is, in the acceleration tube 13, the electric field generated at the acceleration electrode 14 causes a downward electron flow, that is, an electron beam e. For example, the acceleration electrodes 14 on the upper stage side have higher potential, and the acceleration electrodes 14 on the lower stage side have lower potential.

A scanning tube 16 is connected to the acceleration tube 13 at a lower end unit thereof. The acceleration tube 13 and the scanning tube 16 communicate with each other through an internal space 17, and the electron beam e advances from the acceleration tube 13 toward the scanning tube 16 in the internal space 17. The scanning tube 16 has a narrow upper end unit and a shape that widens toward the bottom. The scanning tube 16 is provided with a scanning coil 18 at the narrow upper end unit thereof. The scanning coil 18 deflects the direction of the electron beam e generated in the acceleration tube 13 based on the energization thereof, that is, scans the electron beam e.

An opening window unit 19 of a substantially rectangular shape is provided at the lower end unit of the scanning tube 16, for example. A window foil 20 of a substantially rectangular shape is attached to the opening window unit 19. The window foil 20 is a very thin metal foil, and is made of, for example, a titanium-based metal material. The window foil 20 has the function of sealing the opening window unit 19 while transmitting the electron beam e. In other words, the internal space 17 spanning the acceleration tube 13 and the scanning tube 16 is configured as a sealed space. The internal space 17 is kept in a vacuum state, for example, by driving a vacuum pump 21 connected to the scanning tube 16, at least during the period when the electron beam e is generated.

The filament power supply 12, the acceleration electrode power supply 15, the scanning coil 18, and the vacuum pump 21 described above are controlled by a control device 22. The control device 22 adjusts the output of the electron beam e through the filament power supply 12 and the acceleration electrode power supply 15, controls the scanning of the electron beam e through the scanning coil 18, and adjusts the vacuum of the internal space 17 of the acceleration tube 13.

Then, the electron beam e emitted through the window foil 20 attached to the opening window unit 19 is irradiated onto a workpiece 24, which is transported in a transport direction x by a transport device 23, for example. In this case, the electron beam irradiation device 10 is disposed such that a longitudinal direction of the opening window unit 19 of a substantially rectangular shape is directed in a transport orthogonal direction y of the transport device 23. A predetermined scan of the electron beam e including the transport direction x and the transport orthogonal direction y is performed, and an irradiation area A of a substantially rectangular shape corresponding to the opening window unit 19 is irradiated. The effect of irradiating the workpiece 24 with the electron beam e can be expected to be, for example, improving the properties of materials of, adding functions to, and sterilizing the workpiece 24.

### Configuration of Pressure Tank 32

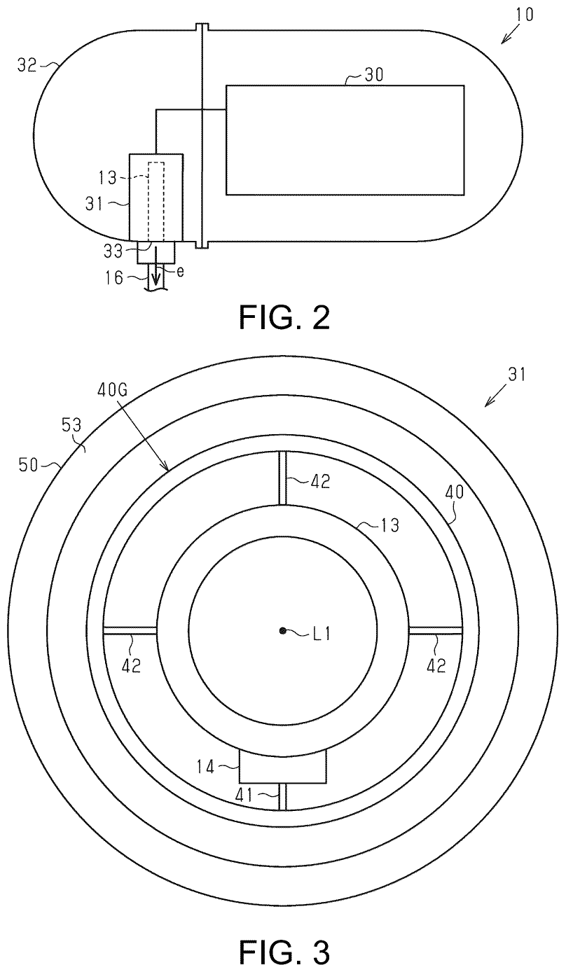

As shown in FIG. 2, the power supply device 30 and an acceleration tube unit 31 are housed inside a pressure tank 32. The acceleration tube unit 31 includes the filament 11, the acceleration tube 13 including each of the acceleration electrodes 14, a shield ring 40 described below, and a shield member 50 described below. The inside of the pressure tank 32 is filled with an insulating gas such as an SF6 gas. The internal pressure of the pressure tank 32 is set to a high pressure of about 0.5 MPa, for example. The pressure tank 32 is made of a conductor such as metal, for example. Note that the pressure tank 32 is, for example, electrically grounded. The pressure tank 32 has an exit port 33 for emitting the electron beam e emitted from the acceleration tube 13 to the outside of the pressure tank 32.

### Configuration of Acceleration Tube Unit 31

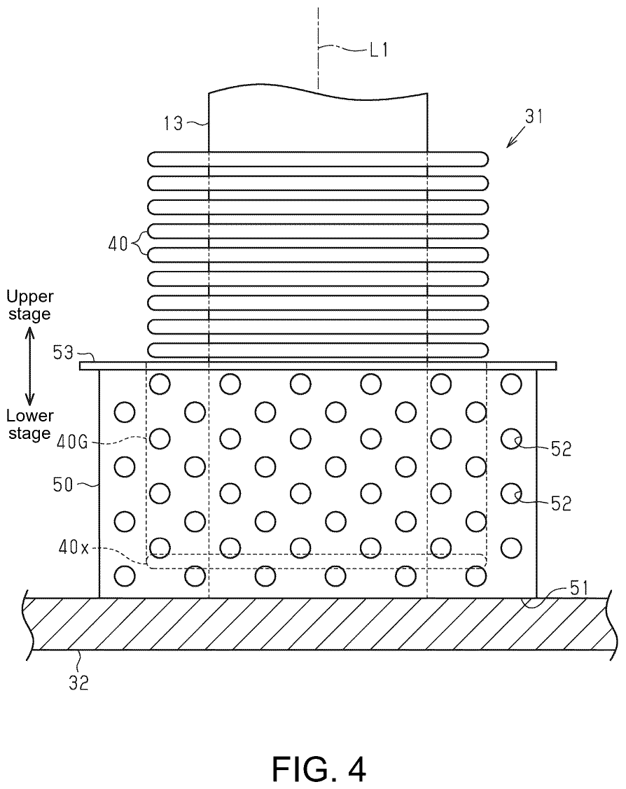

As shown in FIGS. 3 and 4, the acceleration tube 13 has, for example, a cylindrical shape that is long in the axis L1 direction. The acceleration tube 13 is made of, for example, an insulator such as glass. Multiple acceleration electrodes 14 are integrated into the acceleration tube 13.

The acceleration tube unit 31 includes a shield ring 40 around the acceleration tube 13. The shield ring 40 has, for example, an annular shape centered on the axis L1 of the acceleration tube 13. Multiple shield rings 40 are provided corresponding to the acceleration electrodes 14, respectively. The shield rings 40 are disposed in parallel in the axis L1 direction. Each of the shield rings 40 is electrically connected to the corresponding acceleration electrode 14 so as to have the same potential. Note that the shield ring 40 is made of, for example, a conductive material such as metal, and is electrically connected to the acceleration electrode 14 through a connection conductor 41 that may be integrated with or separate from the acceleration electrode 14. The shield ring 40 is provided to alleviate the electric field around the acceleration tube 13. Note that each of the shield rings 40 is supported on the acceleration tube 13 side by a support unit 42. In the following description, the shield rings 40 may be collectively referred to as a ring group 40G.

The acceleration tube unit 31 includes a conductive shield member 50. The shield member 50 has, for example, a substantially cylindrical shape centered on the axis L1 of the acceleration tube 13. The shield member 50 is, for example, a metal plate formed into a cylinder. The shield member 50 surrounds a radially outer side of the ring group 40G.

As shown in FIG. 4, an end unit 51 of the lower stage side of the shield member 50 is connected to the pressure tank 32. Therefore, the shield member 50 is supported by the pressure tank 32. Further, the shield member 50 is electrically connected to the pressure tank 32 and has the same potential as the pressure tank 32. Further, the shield member 50 is configured to be detachable from the pressure tank 32. Therefore, the shield member 50 can be removed during maintenance of the acceleration tube 13 and the like, resulting in good workability.

For example, the shield member 50 surrounds a portion in the axis L1 direction in the ring group 40G. In the axis L1 direction, the range that the shield member 50 surrounds the ring group 40G is approximately half the range on the lower stage side. Therefore, the shield member 50 surrounds a radially outer side of a lowermost shield ring 40x in the ring group 40G.

The shield member 50 includes a heat release hole 52 which penetrates from an inner circumferential side to an outer circumferential side of the shield member 50. For example, multiple heat release holes 52 are provided. Heat generated in the acceleration electrodes 14 are efficiently released to the outside of the shield member 50 from each of the heat release holes 52.

The shield member 50 further includes a flange unit 53 extending radially outward from an end unit of the upper stage side. The flange unit 53 is provided, for example, over the entire circumference of the end unit of the upper stage side of the shield member 50. By providing the flange unit 53, the end unit of the upper stage side of the shield member 50 does not have a cut edge.

The operation of the embodiment will be described.

In the pressure tank 32, for example, an unstable electric field is emitted from the power supply device 30, and the unstable electric field may affect the surroundings of the acceleration tube unit 31. In the embodiment, the shield member 50 is at ground potential through the pressure tank 32. Therefore, inside the shield member 50, the electric field around the acceleration tube 13 is stabilized at substantially the same cylindrical potential. Therefore, the voltage of each of the acceleration electrodes 14 is stabilized, and as a result, it becomes easier to obtain desired characteristics of the electron beam e accelerated in the acceleration tube 13.

Moreover, since the shield member 50 is set to the ground potential, the potential difference between the acceleration electrode 14 and the shield ring 40 increases toward the upper stage side. In this respect, the shield member 50 of the embodiment surrounds a portion of the range of the lower stage side of the ring group 40G, but does not surround the range of the upper stage side of the ring group 40G. Therefore, the occurrence of a short circuit due to discharge between the shield ring 40 and the shield member 50 is suppressed.

Further, by providing the flange unit 53 at the end unit of the upper stage side of the shield member 50, the end unit of the upper stage side does not have a cut edge. In this way, the occurrence of a short circuit due to discharge between the end unit of the upper stage side of the shield member 50 and the shield ring 40 is suppressed.

The effects of the embodiment will be described.
(1) Multiple shield rings 40 are disposed in parallel in the axis L1 direction so as to form a pair with the acceleration electrodes 14 on the radially outer side of the acceleration tube 13, and the shield rings 40 respectively are electrically connected to the acceleration electrodes 14 that form the pair therewith. The conductive shield member 50 surrounds the radially outer side of the ring group 40G made up of multiple shield rings 40. Further, the shield member 50 surrounds at least a portion in the axis L1 direction in the ring group 40G.

According to the configuration, the influence of an unstable electric field around the shield ring 40 on the acceleration tube 13 may be suppressed by the shield member 50. Such a way makes it easier to obtain desired characteristics of the electron beam e accelerated in the acceleration tube 13, thereby contributing to stabilizing the performance of the electron beam irradiation device 10, for example. Further, by reducing the influence of the unstable electric field around the shield ring 40, the beam trajectory of the electron beam e, which depends on the electric field within the acceleration tube 13, is stabilized. Therefore, extension of the service life of parts such as the acceleration tube 13, the scanning tube 16, and the window foil 20 can also be expected.
(2) The electron beam irradiation device 10 includes the power supply device 30 which supplies power to the acceleration tube 13; and the pressure tank 32 which accommodates the acceleration tube 13, the ring group 40G, the shield member 50, and the power supply device 30. According to the configuration, an unstable electric field is generated from the power supply device 30 within the pressure tank 32, and the unstable electric field may affect the surroundings of the acceleration tube 13. The inside of the pressure tank 32 is a closed space filled with an insulating gas, and the electric field generated by the power supply device 30 housed inside thereof has a more significant influence on the acceleration tube unit 31. In this regard, since the electron beam irradiation device 10 includes the shield member 50, the influence of the unstable electric field generated by the power supply device 30 on the acceleration tube 13 can be suitably suppressed by the shield member 50.
(3) The shield member 50 is electrically connected to the pressure tank 32 and has the same potential as the pressure tank 32. According to the configuration, by setting the shield member 50 at the same potential as the pressure tank 32, the electric field around the acceleration tube 13 inside the shield member 50 may be suitably stabilized.
(4) The acceleration tube 13 includes the filament 11 at one end unit of the acceleration tube 13 in the axis L1 direction as a thermionic emission unit that emits thermoelectrons. In the axis L1 direction of the acceleration tube 13, the end unit side where the filament 11 is provided is defined as the upper stage side, the opposite side thereof is defined as the lower stage side, and the acceleration tube 13 emits the accelerated electron beam e from the end unit of the lower stage side. Then, the pressure tank 32 has an exit port 33 for emitting the electron beam e emitted from the end unit of the lower stage side of the acceleration tube 13 to the outside of the pressure tank 32. According to the configuration, the electron beam e emitted from the acceleration tube 13 may be emitted to the outside of the pressure tank 32 through the exit port 33.
(5) The shield member 50 surrounds a portion in the axis L1 direction in the ring group 40G. Then, the shield member 50 surrounds the radially outer side of the lowermost shield ring 40x in the ring group 40G. According to the configuration, the potential difference between the shield member 50 and the shield ring 40 is larger toward the upper stage side. Therefore, by configuring the shield member 50 to surround a portion of the lower stage side of the ring group 40G, the occurrence of a short circuit due to discharge between the shield ring 40 and the shield member 50 may be suppressed. Furthermore, by suppressing the occurrence of a short circuit due to discharge between the shield ring 40 and the shield member 50, the distance between the shield member 50 and the shield ring 40 in the radial direction may be configured to be shorter. As a result, the size of the shield member 50 in the radial direction may be reduced.
(6) The shield member 50 includes the heat release hole 52 which penetrates from the inner circumferential side to the outer circumferential side of the shield member 50.

According to the configuration, for example, heat generated in the acceleration electrode 14 may be efficiently discharged to the outside of the shield member 50. The electron beam irradiation device 10 of the embodiment is of a horizontal irradiation type in which the axis L1 direction of the acceleration tube 13 is oriented in the horizontal direction. In the electron beam irradiation device 10 of a horizontal irradiation type, for example, when the acceleration electrode 14 is bonded to the acceleration tube 13, if the inside of the shield member 50 becomes high temperature and the adhesive bonding the acceleration electrode 14 melts, the acceleration electrode 14 may come off from the acceleration tube 13 due to the weight of the acceleration electrode 14 itself. In this regard, providing the heat release hole 52 in the shield member 50 suppresses a temperature rise inside the shield member 50, thereby suppressing the acceleration electrode 14 from coming off from the acceleration tube 13.
(7) The shield member 50 includes the flange unit 53 extending radially outward from the end unit of the upper stage side. In this way, the end unit of the upper stage side of the shield member 50 does not have a cut edge. As a result, the occurrence of a short circuit due to discharge between the end unit of the upper stage side of the shield member 50 and the shield ring 40 may be suppressed.

The embodiment can be modified and implemented as follows. The embodiment and the following modified examples can be implemented in combination with each other within a technically consistent range.

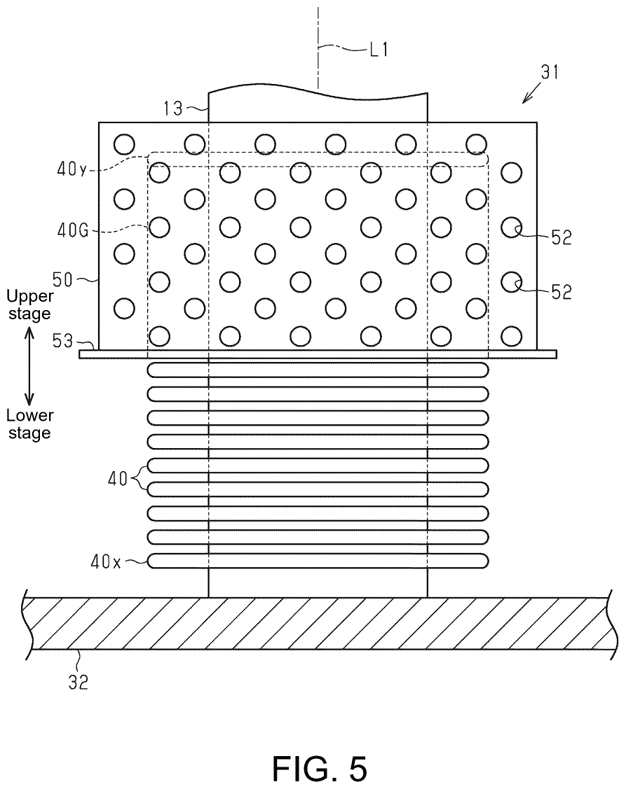

As shown in FIG. 5, the shield member 50 may be configured to surround a portion of the upper stage side of the ring group 40G. In this case, the shield member 50 is preferably not at the same potential as the pressure tank 32 but at the same potential as the high potential on the upper stage side (power supply device 30 side). Further, in the configuration shown in FIG. 5, the shield member 50 surrounds a radially outer side of an uppermost shield ring 40y in the ring group 40G. Further, in the same configuration, the flange unit 53 is provided at the end unit of the lower stage side of the shield member 50.

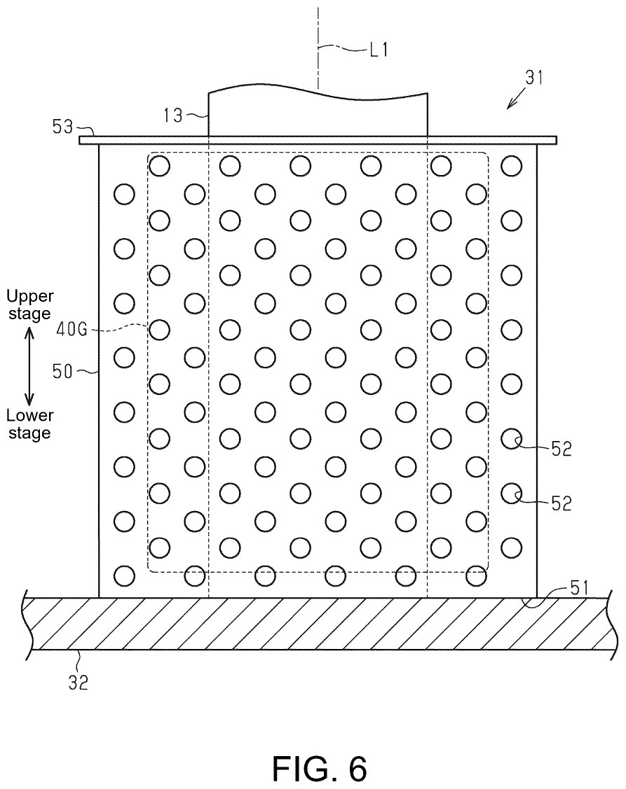

As shown in FIG. 6, the shield member 50 may be configured to surround all in the axis L1 direction in the ring group 40G. According to the configuration, the influence of the unstable electric field around the shield ring 40 on the acceleration tube 13 may be more effectively suppressed by the shield member 50.

The shield member 50 does not necessarily need to surround the radially outer side of the lowermost shield ring 40x or the uppermost shield ring 40y. That is, the shield member 50 may be configured to surround merely the shield ring 40 that is the middle portion in the axis L1 direction in the ring group 40G.

In the above embodiment, although a horizontal irradiation type is used in which the axis L1 direction of the acceleration tube 13 is oriented in the horizontal direction, the present invention is not limited thereto, and, for example, a vertical irradiation type in which the axis L1 direction of the acceleration tube 13 is oriented in the vertical direction may be used. Alternatively, the axis L1 direction of the acceleration tube 13 may be configured to face neither the horizontal direction nor the vertical direction.

In the shield member 50, the heat release hole 52 may be omitted. When the electron beam irradiation device 10 is of the vertical irradiation type, since the risk of the acceleration electrode 14 coming off due to the orientation of the acceleration tube 13 is reduced, the problem of temperature rise inside the shield member 50 is less likely to occur compared to the horizontal irradiation type.

The shield member 50 of the above embodiment is formed from a plate-shaped material such as a metal plate, but is not particularly limited thereto. For example, the shield member 50 may be a mesh member made of woven metal wires, for example. By using the shield member 50 as a mesh member, the shield member 50 can have high heat dissipation properties, and as a result, the temperature rise inside the shield member 50 may be suppressed.

Although the pressure tank 32 is set to the ground potential in the above embodiment, the potential of the pressure tank 32 is not particularly limited thereto, and the potential of the pressure tank 32 may be changed as appropriate depending on the configuration.

The embodiment and modified examples disclosed this time are illustrative in all respects, and the present invention is not limited to these illustrative examples. That is, the scope of the present invention is indicated by the scope of the claims, and is intended to include all modifications within the meaning and scope equivalent to the scope of the claims.

### REFERENCE SIGNS LIST

10 . . . Electron beam irradiation device
11 . . . Filament (thermionic emission unit)
13 . . . Acceleration tube
14 . . . Acceleration electrode
30 . . . Power supply device
32 . . . Pressure tank
33 . . . Exit port
40 . . . Shield ring
40G . . . Ring group
40x . . . Lowermost shield ring
50 . . . Shield member
52 . . . Heat release hole
e . . . Electron beam
L1 . . . Axis

1. An electron beam irradiation device, comprising:
an acceleration tube, comprising a plurality of acceleration electrodes disposed in parallel in an axis direction for generating an electric field for accelerating an electron beam; and
a plurality of shield rings, disposed in parallel in the axis direction so as to form a pair with the acceleration electrodes on a radially outer side of the acceleration tube, and the shield rings respectively being electrically connected to the acceleration electrodes that form the pair therewith, wherein
the electron beam irradiation device comprises a conductive shield member surrounding a radially outer side of a ring group composed of the plurality of shield rings, and
the shield member surrounds at least a portion in the axis direction in the ring group.

2. The electron beam irradiation device according to claim 1, further comprising:
a power supply device, supplying power to the acceleration tube; and
a pressure tank, accommodating the acceleration tube, the ring group, the shield member, and the power supply device.

3. The electron beam irradiation device according to claim 2, wherein
the shield member is electrically connected to the pressure tank and has the same potential as the pressure tank.

4. The electron beam irradiation device according to claim 3, wherein
the acceleration tube comprises a thermionic emission unit which emits thermoelectrons at one end unit in the axis direction of the acceleration tube,
in the axis direction of the acceleration tube, an end unit side where the thermionic emission unit is provided is an upper stage side, and an opposite side thereof is a lower stage side,
the acceleration tube emits an accelerated electron beam from an end unit of the lower stage side, and
the pressure tank comprises an exit port for emitting the electron beam emitted from the end unit of the lower stage side of the acceleration tube to the outside of the pressure tank.

5. The electron beam irradiation device according to claim 4, wherein
the shield member surrounds a portion in the axis direction in the ring group, and
the shield member surrounds a radially outer side of at least the lowermost stage of the shield ring in the ring group.

6. The electron beam irradiation device according to claim 1, wherein
the shield member surrounds all in the axis direction in the ring group.

7. The electron beam irradiation device according to claim 1, wherein
the shield member comprises a heat release hole which penetrates from an inner circumferential side to an outer circumferential side of the shield member.
